(19) United States
(12) Patent Application Publication
(10) Pub. No.: US 2024/0128139 A1
(43) Pub. Date: Apr. 18, 2024

(54) SENSOR PACKAGE STRUCTURE

(71) Applicant: TONG HSING ELECTRONIC INDUSTRIES, LTD., Taipei City (TW)

(72) Inventors: WEI-LI WANG, Taipei City (TW); JYUN-HUEI JIANG, Taipei City (TW); WEN-FU YU, Taipei City (TW); BAE-YINN HWANG, Taipei City (TW); CHIEN-HUNG LIN, Taipei City (TW)

(21) Appl. No.: 18/206,153

(22) Filed: Jun. 6, 2023

Related U.S. Application Data
(60) Provisional application No. 63/416,721, filed on Oct. 17, 2022.

(30) Foreign Application Priority Data
Mar. 23, 2023 (TW) 112110804

(51) Int. Cl. H01L 23/31; H01L 23/00; H01L 25/065

(52) U.S. Cl. CPC H01L 23/3114; H01L 23/3121; H01L 23/3142; H01L 24/29; H01L 25/0655

(57) ABSTRACT

A sensor package structure includes a substrate, a sensor chip disposed on the substrate along a predetermined direction for being electrically coupled to each other, a light-permeable layer, an adhesive layer having a ring-shape and sandwiched between the sensor chip and the light-permeable layer, and an encapsulant formed on the substrate. The adhesive layer is formed with at least one type of a buffering cavity, wave-shaped slots, and rectangular slots, which penetrate therethrough along the predetermined direction. The buffering cavity can be located in the adhesive layer, and any one type of the wave-shaped slots and the rectangular slots can be respectively recessed in an inner side and an outer side of the adhesive layer. A minimum width of the adhesive layer is greater than or equal to 50% of a predetermined width between the inner side and the outer side.

### CROSS-REFERENCE TO RELATED PATENT APPLICATION

This application claims the benefit of priority to Taiwan Patent Application No. 112110804, filed on Mar. 23, 2023. The entire content of the above identified application is incorporated herein by reference.

This application claims the benefit of priority to the U.S. Provisional Patent Application Ser. No. 63/416,721 filed on Oct. 17, 2022, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a sensor package structure.

### BACKGROUND OF THE DISCLOSURE

A conventional sensor package structure includes a light-permeable sheet, a sensor chip, and an adhesive layer that is adhered to and sandwiched between the light-permeable sheet and the sensor chip. However, the adhesive layer has a larger coefficient of thermal expansion (CTE), so that when the conventional sensor package structure has a high temperature (or is heated), the adhesive layer and a component bonded thereon has a stress therebetween that can lead to a delamination issue or damage of the component.

### SUMMARY OF THE DISCLOSURE

In response to the above-referenced technical inadequacies, the present disclosure provides a sensor package structure to effectively improve on the issues associated with conventional sensor package structures.

In order to solve the above-mentioned problems, one of the technical aspects adopted by the present disclosure is to provide a sensor package structure, which includes a substrate, a sensor chip, an adhesive layer, a light-permeable layer, and an encapsulant. The sensor chip is disposed on the substrate along a predetermined direction and is electrically coupled to the substrate. Moreover, a top surface of the sensor chip has a sensing region and a carrying region that surrounds the sensing region. The adhesive layer has a ring shape and is disposed on the carrying region of the sensor chip. The adhesive layer has an inner side and an outer side that is opposite to the inner side and that is spaced apart from the inner side by a predetermined width along a width direction perpendicular to the predetermined direction. The adhesive layer has at least one type of the following recesses: L number of buffering cavities, M number of wave-shaped slots, and N number of rectangular slots, where L is a positive integer, any one of M and N is a positive integer greater than one. In a cross-sectional view of the adhesive layer perpendicular to the predetermined direction, a minimum width of the adhesive layer in the width direction is greater than or equal to 50% of the predetermined width. The light-permeable layer has an outer surface and an inner surface that is opposite to the outer surface. The light-permeable layer is disposed on the adhesive layer, and the inner surface of the light-permeable layer, the inner side of the adhesive layer, and the sensor chip jointly define an enclosed space. The encapsulant is formed on the substrate. The sensor chip, the adhesive layer, and the light-permeable layer are embedded in the encapsulant, and the outer surface of the light-permeable layer is at least partially exposed from the encapsulant. When the adhesive layer has the L number of the buffering cavities, each of the L number of the buffering cavities is arranged in the adhesive layer and penetrates through the adhesive layer along the predetermined direction. When the adhesive layer has the M number of the wave-shaped slots, the M number of the wave-shaped slots are respectively recessed in the inner side and the outer side of the adhesive layer and penetrate through the adhesive layer along the predetermined direction, and any two of the M number of the wave-shaped slots located adjacent to each other and respectively arranged on the inner side and the outer side are only partially overlapped with each other along the width direction. When the adhesive layer has the N number of the rectangular slots, the N number of the rectangular slots are respectively recessed in the inner side and the outer side of the adhesive layer and penetrate through the adhesive layer along the predetermined direction, and any two of the N number of the rectangular slots located adjacent to each other and respectively arranged on the inner side and the outer side are not overlapped with each other along the width direction.

In order to solve the above-mentioned problems, another one of the technical aspects adopted by the present disclosure is to provide a sensor package structure, which includes a substrate, a sensor chip, an adhesive layer, a light-permeable layer, and an encapsulant. The sensor chip is disposed on the substrate along a predetermined direction and electrically coupled to the substrate. Moreover, a top surface of the sensor chip has a sensing region and a carrying region that surrounds the sensing region. The adhesive layer has a ring shape and is disposed on the carrying region of the sensor chip. The adhesive layer has an inner side and an outer side that is opposite to the inner side and that is spaced apart from the inner side by a predetermined width along a width direction perpendicular to the predetermined direction. The adhesive layer has a plurality of wave-shaped slots respectively recessed in the inner side and the outer side thereof and penetrating therethrough along the predetermined direction. Any two of the wave-shaped slots located adjacent to each other and respectively arranged on the inner side and the outer side are only partially overlapped with each other along the width direction. In a cross-sectional view of the adhesive layer perpendicular to the predetermined direction, a minimum width of the adhesive layer in the width direction is greater than or equal to 50% of the predetermined width. The light-permeable layer has an outer surface and an inner surface that is opposite to the outer surface. The light-permeable layer is disposed on the adhesive layer, and the inner surface of the light-permeable layer, the inner side of the adhesive layer, and the sensor chip jointly define an enclosed space. The encapsulant is formed on the substrate. The sensor chip, the adhesive layer, and the light-permeable layer are embedded in the encapsulant, and the outer surface of the light-permeable layer is at least partially exposed from the encapsulant.

In order to solve the above-mentioned problems, yet another one of the technical aspects adopted by the present disclosure is to provide a sensor package structure, which includes a substrate, a sensor chip, an adhesive layer, a light-permeable layer, and an encapsulant. The sensor chip is disposed on the substrate along a predetermined direction and is electrically coupled to the substrate. Moreover, a top surface of the sensor chip has a sensing region and a carrying region that surrounds the sensing region. The adhesive layer has a ring shape and is disposed on the carrying region of the sensor chip. The adhesive layer has an inner side and an outer side that is opposite to the inner side and that is spaced apart from the inner side by a predetermined width along a width direction perpendicular to the predetermined direction. The adhesive layer has a plurality of rectangular slots respectively recessed in the inner side and the outer side thereof and penetrating therethrough along the predetermined direction. Any two of the rectangular slots located adjacent to each other and respectively arranged on the inner side and the outer side are not overlapped with each other along the width direction. In a cross-sectional view of the adhesive layer perpendicular to the predetermined direction, a minimum width of the adhesive layer in the width direction is greater than or equal to 50% of the predetermined width. The light-permeable layer has an outer surface and an inner surface that is opposite to the outer surface. The light-permeable layer is disposed on the adhesive layer, and the inner surface of the light-permeable layer, the inner side of the adhesive layer, and the sensor chip jointly define an enclosed space. The encapsulant is formed on the substrate. The sensor chip, the adhesive layer, and the light-permeable layer are embedded in the encapsulant, and the outer surface of the light-permeable layer is at least partially exposed from the encapsulant.

Therefore, when the sensor package structure provided by the present disclosure has a high temperature (or is heated), the adhesive layer can be selectively formed with at least one type of the L number of the buffering cavities, the M number of the wave-shaped slots, and the N number of the rectangular slots (e.g., the adhesive layer has the wave-shaped slots or the rectangular slots), thereby effectively reducing a stress strength generated from the adhesive layer. Accordingly, problems relating to delamination of the adhesive layer or damage of the component adhered to the adhesive layer (e.g., the sensor chip or the light-permeable layer) can be improved.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a sensor package structure in a first configuration according to an embodiment of the present disclosure;

FIG. 2 is a schematic cross-sectional view taken along line II-II of FIG. 1;

FIG. 3 is a schematic top view of FIG. 1 with a light-permeable layer and an encapsulant being omitted;

FIG. 4 is an enlarged view of part IV of FIG. 3;

FIG. 5 is a partial schematic top view showing the sensor package structure in a second configuration with the light-permeable layer and the encapsulant being omitted;

FIG. 6 is a partial schematic top view showing the sensor package structure in a third configuration with the light-permeable layer and the encapsulant being omitted;

FIG. 7 is a partial schematic top view showing the sensor package structure in another third configuration when the light-permeable layer and the encapsulant are omitted;

FIG. 8 is a partial schematic top view showing the sensor package structure in a fourth configuration when the light-permeable layer and the encapsulant are omitted;

FIG. 9 is a partial schematic top view showing the sensor package structure in a fifth configuration when the light-permeable layer and the encapsulant are omitted;

FIG. 10 is a partial schematic top view showing the sensor package structure in a sixth configuration when the light-permeable layer and the encapsulant are omitted; and

FIG. 11 is a partial schematic top view showing the sensor package structure in a seventh configuration when the light-permeable layer and the encapsulant are omitted.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

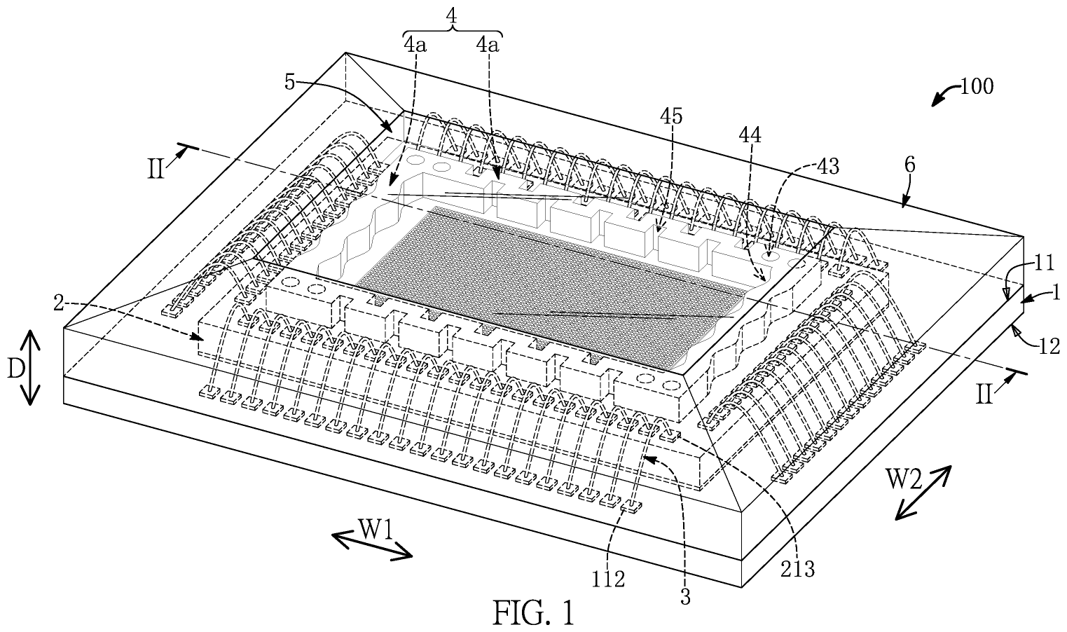

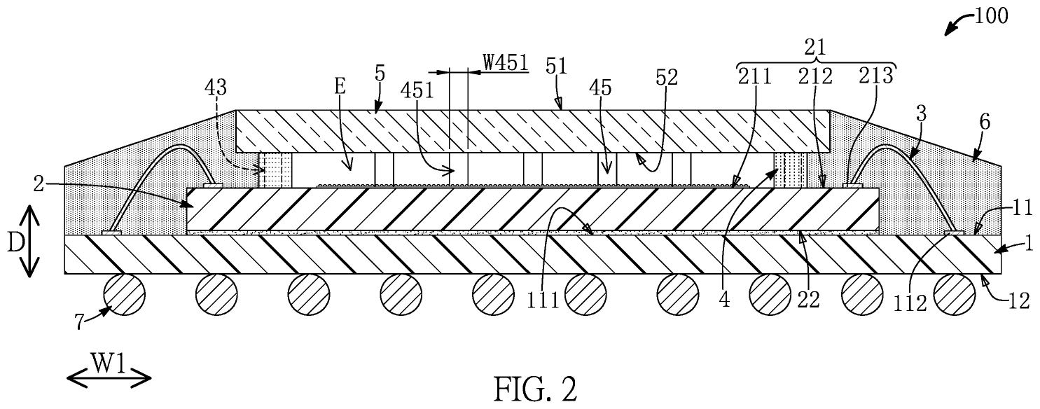

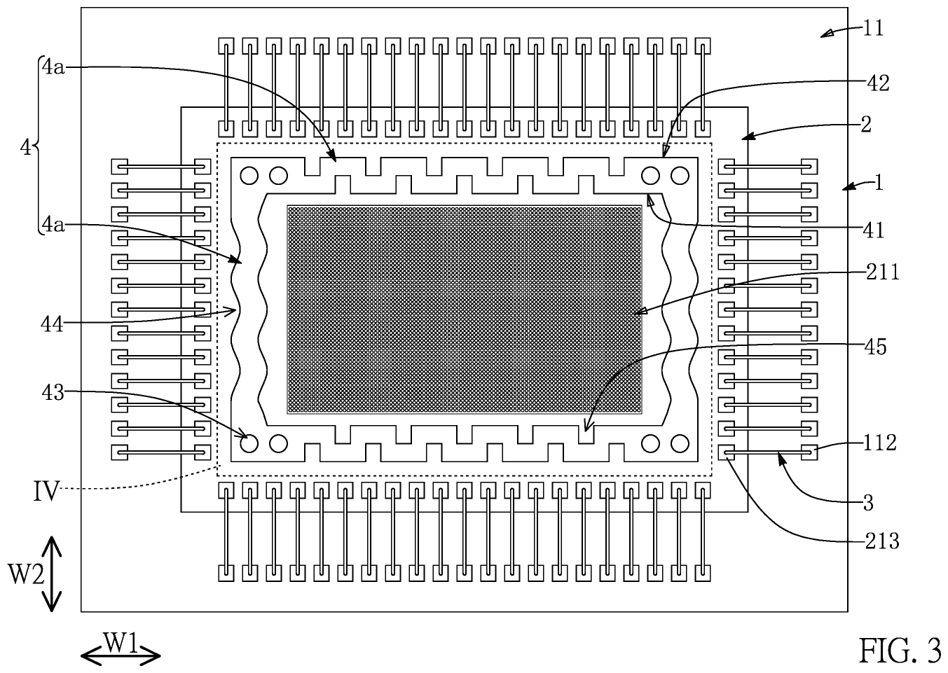

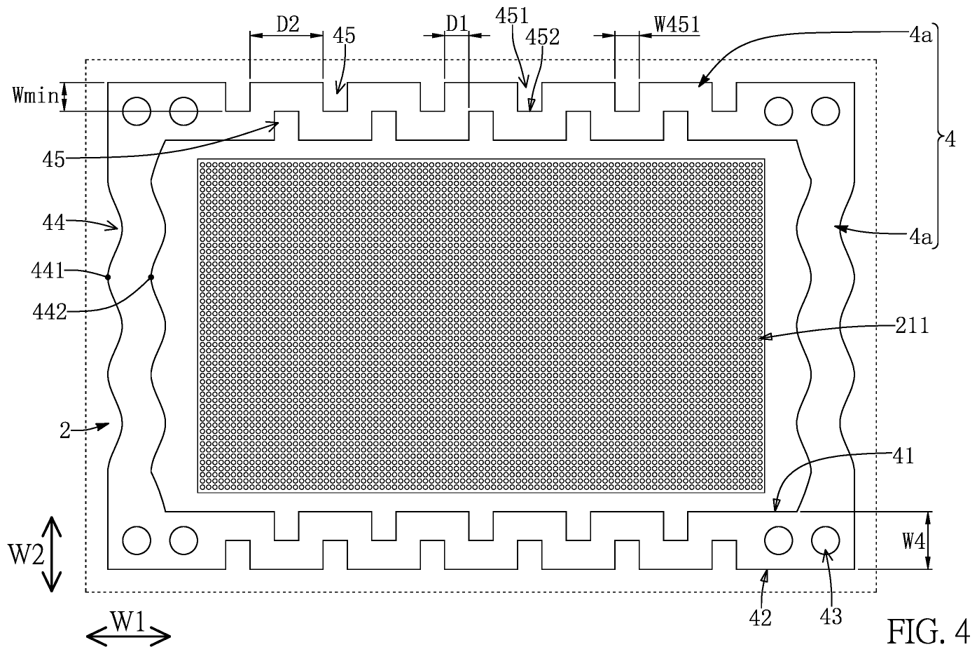

Referring to FIG. 1 to FIG. 11, an embodiment of the present disclosure is provided. The present embodiment provides a sensor package structure 100. In other words, any package structure not encapsulating a sensor chip therein has a structural design different from that of the sensor package structure 100 of the present embodiment.

As shown in FIG. 1 to FIG. 4, the sensor package structure 100 includes a substrate 1, a sensor chip 2 disposed on the substrate 1, a plurality of metal wires 3 electrically coupled to the sensor chip 2 and the substrate 1, an adhesive layer 4 having a ring shape and being disposed on the sensor chip 2, a light-permeable layer 5 disposed on the adhesive layer 4, and an encapsulant 6 that is formed on the substrate 1.

The sensor package structure 100 in the present embodiment includes the above components, but can be adjusted or changed according to design requirements. For example, in other embodiments of the present disclosure not shown in the drawings, the sensor package structure 100 can be provided without the metal wires 3, and the sensor chip 2 is fixed onto and electrically coupled to the substrate 1 in a flip-chip manner or an adhering manner. The structure and connection relationship of each component of the sensor package structure 100 will be recited in the following description.

The substrate 1 of the present embodiment has a square shape or a rectangular shape, but the present disclosure is not limited thereto. An upper surface 11 of the substrate 1 includes a chip-bonding region 111 arranged approximately on a center portion thereof, and the substrate 1 includes a plurality of bonding pads 112 that are disposed on the upper surface 11 and are arranged outside of the chip-bonding region 111. The bonding pads 112 in the present embodiment are in a ring-shaped arrangement, but the present disclosure is not limited thereto. For example, in other embodiments of the present disclosure not shown in the drawings, the bonding pads 112 can be arranged in two rows respectively at two opposite sides of the chip-bonding region 111.

In addition, the substrate 1 can be further provided with a plurality of solder balls 7 disposed on a lower surface 12 thereof. The substrate 1 can be soldered onto an electronic component (not shown in the drawings) through the solder balls 7, thereby electrically connecting the sensor package structure 100 to the electronic component.

The sensor chip 2 in the present embodiment has a square shape or a rectangular shape and is an image sensor chip, but the present disclosure is not limited thereto. A bottom surface 22 of the sensor chip 2 is fixed onto the chip-bonding region 111 of the substrate 1 (through a chip-bonding adhesive) along a predetermined direction D. In other words, the sensor chip 2 is arranged to be surrounded on the inside of the bonding pads 112. Moreover, a top surface 21 of the sensor chip 2 has a sensing region 211 and a carrying region 212 that has a ring shape arranged around the sensing region 211. Two ends of each of the metal wires 3 are respectively connected to the substrate 1 and the carrying region 212 of the sensor chip 2, so that the substrate 1 and the sensor chip 2 are electrically coupled to each other.

Specifically, the sensor chip 2 includes a plurality of connection pads 213 arranged on the carrying region 212. In other words, the connection pads 213 are arranged outside of the sensing region 211. The number and positions of the connection pads 213 of the sensor chip 2 in the present embodiment correspond to those of the bonding pads 112 of the substrate 1. In other words, the connection pads 213 in the present embodiment are substantially in a ring-shaped arrangement. Moreover, the two ends of each of the metal wires 3 are respectively connected to one of the bonding pads 112 and the corresponding connection pad 213.

The adhesive layer 4 in the present embodiment includes a plurality of segments 4a sequentially connected to form the ring shape (e.g., a rectangular ring shape) thereof. The adhesive layer 4 is disposed on the carrying region 212 of the sensor chip 2 and surrounds the sensing region 211, and each of the metal wires 3 is located outside of the adhesive layer 4. Moreover, the adhesive layer 4 has an inner side 41 and an outer side 42 that is opposite to the inner side 41 and that is spaced apart from the inner side 41 by a predetermined width W4 along a width direction W1, W2 perpendicular to the predetermined direction D. In the present embodiment, the width direction W1, W2 can be a direction perpendicular to any one of the segments 4a.

Specifically, since the adhesive layer 4 has a larger coefficient of thermal expansion (CTE) (e.g., the CTE of the adhesive layer 4 is at least three times of CTE of the light-permeable layer 5 or CTE of the sensor chip 2), the adhesive layer 4 in the sensor package structure 100 of the present embodiment is selectively formed with at least one type of L number of buffering cavities 43, M number of wave-shaped slots 44, and N number of rectangular slots 45 (e.g., L is a positive integer, and any one of M and N is a positive integer greater than one), thereby effectively reducing a stress strength generated from the adhesive layer 4.

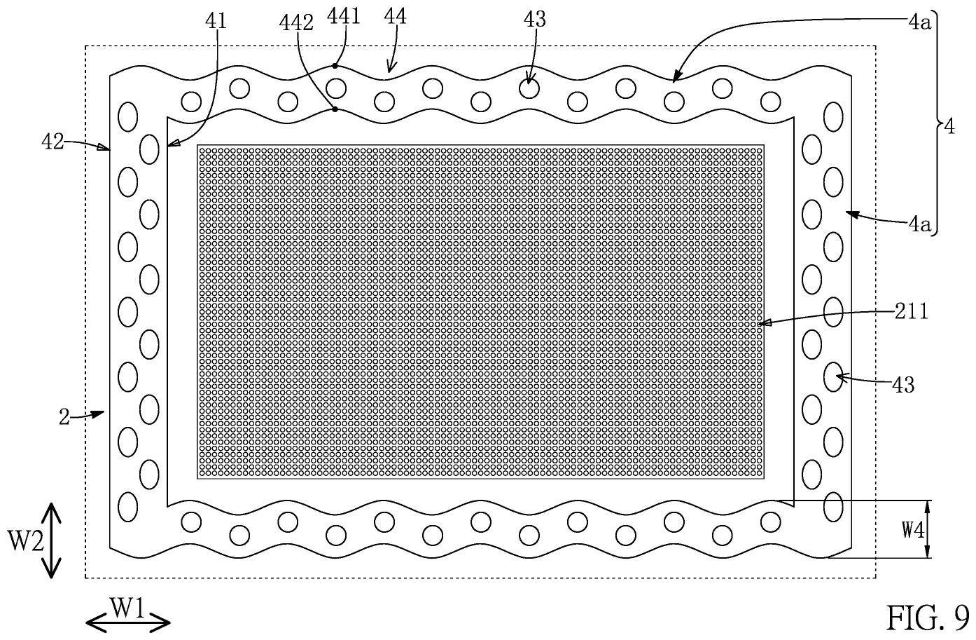

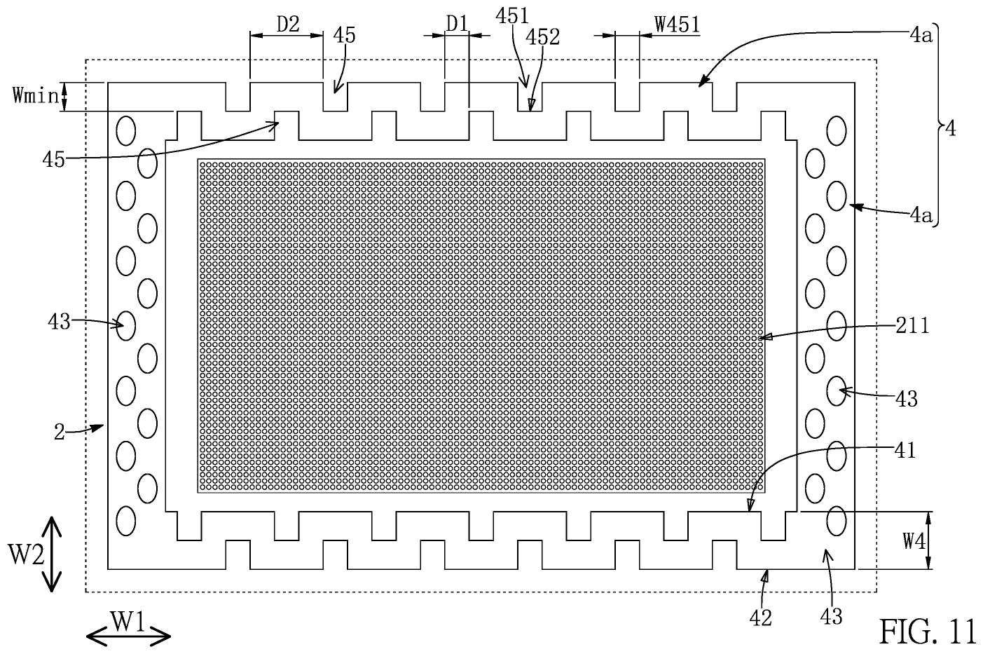

Specifically, when the adhesive layer 4 has the L number of the buffering cavities 43 (as shown in FIG. 1 to FIG. 7, FIG. 9, and FIG. 11), any one of the L number of the buffering cavities 43 is arranged in the adhesive layer 4 and penetrates through the adhesive layer 4 along the predetermined direction D. In other words, the L number of the buffering cavities 43 can be selectively provided and formed in the adhesive layer 4 in the above manner.

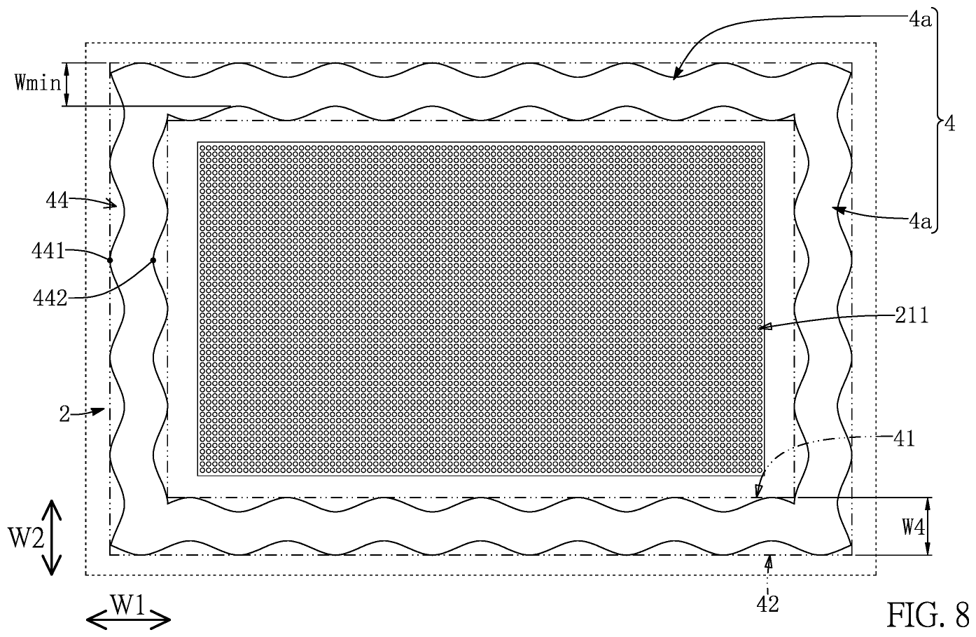

Moreover, when the adhesive layer 4 has the M number of the wave-shaped slots 44 (as shown in FIG. 1 to FIG. 4, FIG. 8, and FIG. 9), the M number of the wave-shaped slots 44 are respectively recessed in the inner side 41 and the outer side 42 of the adhesive layer 4 and penetrate through the adhesive layer 4 along the predetermined direction D, and any two of the M number of the wave-shaped slots 44 located adjacent to each other and respectively arranged on the inner side 41 and the outer side 42 are only partially overlapped with each other along the width direction W1, W2. In other words, the M number of the wave-shaped slots 44 can be selectively provided and formed on the inner side 41 and the outer side 42 of the adhesive layer 4 in the above manner.

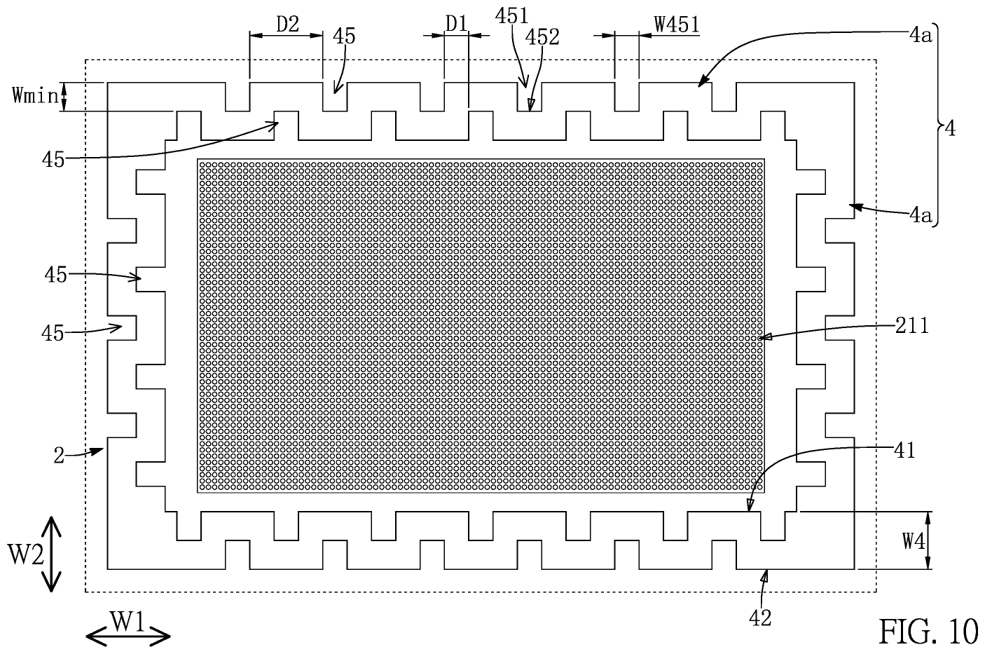

In addition, when the adhesive layer 4 has the N number of the rectangular slots 45 (as shown in FIG. 1 to FIG. 4, FIG. 10, and FIG. 11), the N number of the rectangular slots 45 are respectively recessed in the inner side 41 and the outer side 42 of the adhesive layer 4 and penetrate through the adhesive layer 4 along the predetermined direction D, and any two of the N number of the rectangular slots 45 located adjacent to each other and respectively arranged on the inner side 41 and the outer side 42 are not overlapped with each other along the width direction W1, W2. In other words, the N number of the rectangular slots 45 can be selectively provided and formed on the inner side 41 and the outer side 42 of the adhesive layer 4 in the above manner.

It should be noted that the arrangement of the buffering cavities 43, the wave-shaped slots 44, and the rectangular slots 45 of the adhesive layer 4 in the present embodiment needs to meet the following conditions for preventing the adhesive layer 4 from having insufficient structural strength. In a cross-sectional view of the adhesive layer 4 perpendicular to the predetermined direction D, a minimum width Wmin of the adhesive layer 4 in the width direction W1, W2 is greater than or equal to 50% of the predetermined width W4. Specifically, a position of the minimum width Wmin corresponds to (or is labeled at) a portion of the adhesive layer 4 having a largest ratio of the buffering cavities 43, the wave-shaped slots 44, and/or the rectangular slots 45 along the width direction W1, W2.

The light-permeable layer 5 in the present embodiment is a transparent and flat glass board, but the present disclosure is not limited thereto. The light-permeable layer 5 has an outer surface 51 and an inner surface 52 that is opposite to the outer surface 51. The light-permeable layer 5 (e.g., the inner surface 52) is disposed on the adhesive layer 4, so that the inner surface 52 of the light-permeable layer 5, the inner side 41 of the adhesive layer 4, and the sensor chip 2 jointly define an enclosed space E. The inner side 41 of the adhesive layer 4 and the sensing region 211 of the sensor chip 2 are arranged in the enclosed space E.

The encapsulant 6 of the present embodiment is opaque for blocking a visible light from passing therethrough. The encapsulant 6 is a liquid encapsulation and is formed on the upper surface 11 of the substrate 1, and edges of the encapsulant 6 are flush with edges of the substrate 1. The sensor chip 2, the adhesive layer 4, the light-permeable layer 5, and each of the metal wires 3 are embedded in the encapsulant 6 (e.g., the outer side 42 of the adhesive layer 4 is connected to the encapsulant 6), and the outer surface 51 of the light-permeable layer 5 is at least partially exposed from the encapsulant 6, but the present disclosure is not limited thereto.

In summary, when the sensor package structure 100 of the present embodiment has a high temperature (or is heated), the adhesive layer 4 can be selectively formed with at least one type of the L number of the buffering cavities 43, the M number of the wave-shaped slots 44, and the N number of the rectangular slots 45, thereby effectively reducing a stress strength generated from the adhesive layer 4. Accordingly, problems relating to delamination of the adhesive layer 4 or damage of the component adhered to the adhesive layer 4 (e.g., the sensor chip 2 or the light-permeable layer 5) can be improved.

It should be noted that the above description describes the common features of possible configurations of the adhesive layer 4. For example, FIG. 1 to FIG. 4 show a first configuration of the adhesive layer 4 provided by the present embodiment, and when the adhesive layer 4 has the M number of the wave-shaped slots 44 and the N number of the rectangular slots 45, the M number of the wave-shaped slots 44 are formed on one of the segments 4a, and the N number of the rectangular slots 45 are formed on another one of the segments 4a. Moreover, when the adhesive layer 4 further has the L number of the buffering cavities 43, the L number of the buffering cavities 43 do not correspond along the width direction W1, W2 in position to any one of the M number of the wave-shaped slots 44 and any one of the N number of the rectangular slots 45.

Specifically, a quantity and an arrangement of any one type of the buffering cavities 43, the wave-shaped slots 44, and the rectangular slots 45 formed on the adhesive layer 4 can be adjusted or changed according to design requirements. Moreover, all possible configurations of the adhesive layer 4 cannot be shown in the drawings of the present embodiment, and the following description only describes some preferable configurations of the adhesive layer 4, but the present disclosure is not limited thereto. In addition, in the adhesive layer 4 described in the following description, L is greater than one, but the present disclosure is not limited thereto. For example, in other embodiments of the present disclosure not shown in the drawings, L can be equal to one.

[Second Configuration]

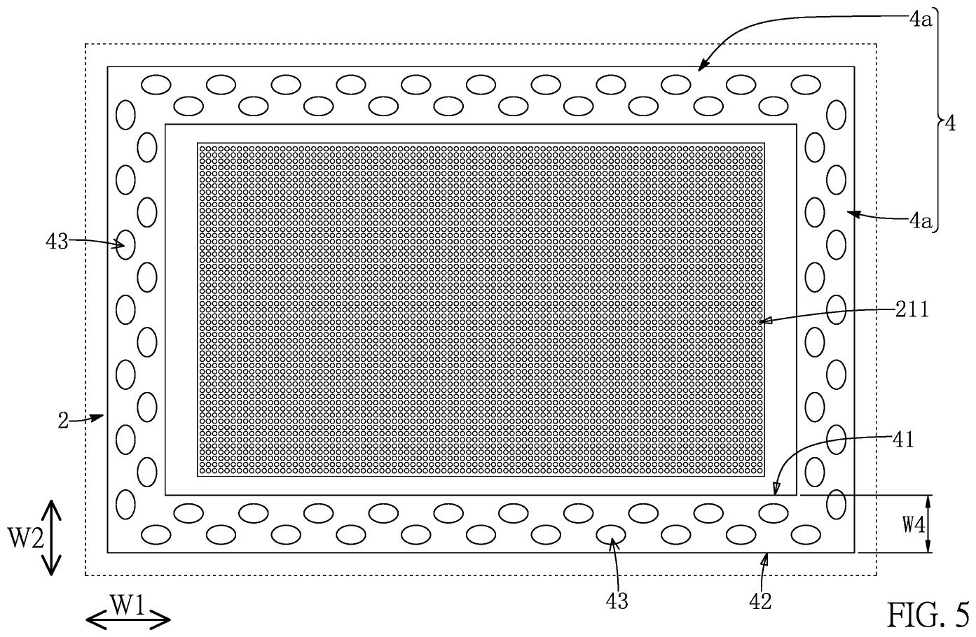

As shown in FIG. 5, the adhesive layer 4 (only) has the buffering cavities 43 respectively formed in the segments 4a. Any two of the buffering cavities 43 located adjacent to each other and arranged on a same one of the segments 4a are not overlapped with each other along the width direction W1, W2. Moreover, any one of the buffering cavities 43 is symmetrical to another one of the buffering cavities 43 relative to a center of the sensing region 211, but the present disclosure is not limited thereto. For example, in other embodiments of the present disclosure not shown in the drawings, the buffering cavities 43 can be only formed in one of the segments 4a of the adhesive layer 4.

Furthermore, in the cross-sectional view of the adhesive layer 4, each of the buffering cavities 43 has an elongated shape (e.g., an ellipse), a total area of the buffering cavities 43 is less than or equal to 50% of an area jointly surrounded by the inner side 41 and the outer side 42 of the adhesive layer 4, thereby effectively preventing the structural strength of the adhesive layer 4 from being insufficient due to the buffering cavities 43.

[Third Configuration]

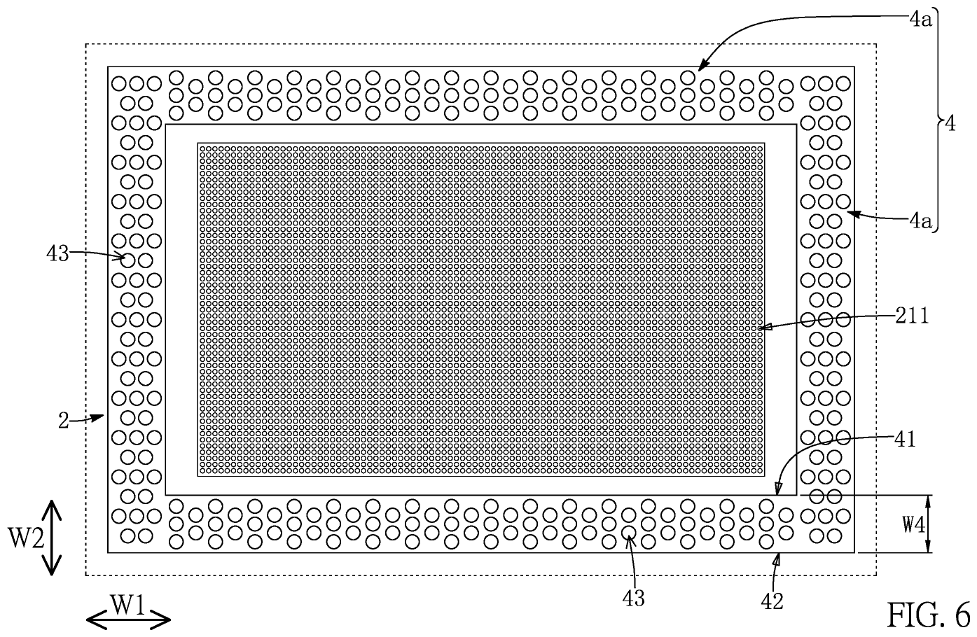

As shown in FIG. 6, the adhesive layer 4 (only) has the buffering cavities 43 respectively formed in the segments 4a. In any two of the buffering cavities 43 arranged on a same one of the segments 4a, one of the any two of the buffering cavities 43 is overlapped with another one of the any two of the buffering cavities 43 along the width direction W1, W2. Moreover, any one of the buffering cavities 43 is symmetrical to another one of the buffering cavities 43 relative to a center of the sensing region 211, but the present disclosure is not limited thereto. For example, in other embodiments of the present disclosure not shown in the drawings, the buffering cavities 43 can be only formed in one of the segments 4a of the adhesive layer 4.

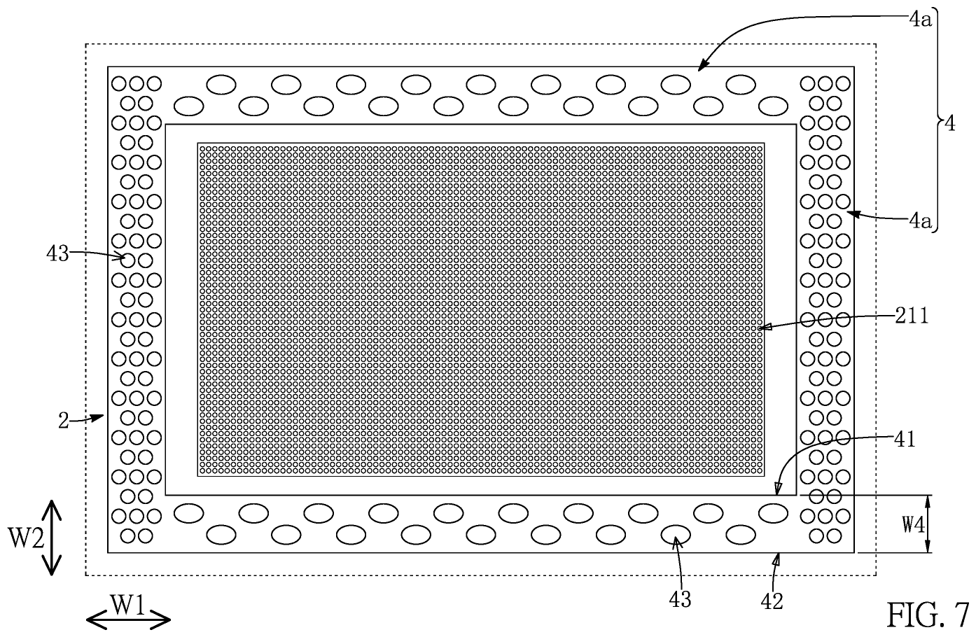

Furthermore, in the cross-sectional view of the adhesive layer 4, each of the buffering cavities 43 has a circular shape, a total area of the buffering cavities 43 is less than or equal to 50% of an area jointly surrounded by the inner side 41 and the outer side 42 of the adhesive layer 4, thereby effectively preventing the structural strength of the adhesive layer 4 from being insufficient due to the buffering cavities 43. Specifically, as shown in FIG. 7, the buffering cavities 43 can be formed of the elongated shape and the circular shape.

### Fourth Embodiment

As shown in FIG. 8, the adhesive layer 4 (only) has the wave-shaped slots 44 respectively formed on the segments 4a. Any two of the wave-shaped slots 44 located adjacent to each other and respectively arranged on the inner side 41 and the outer side 42 are only partially overlapped with each other along the width direction W1, W2, but the present disclosure is not limited thereto. For example, in other embodiments of the present disclosure not shown in the drawings, the wave-shaped slots 44 can be only formed on one of the segments 4a of the adhesive layer 4.

Specifically, in any two of the wave-shaped slots 44 arranged on a same one of the segments 4a, located adjacent to each other, and respectively arranged on the inner side 41 and the outer side 42, a wave crest 441 of one of the two wave-shaped slots 44 corresponds along the width direction W1, W2 in position to a wave trough 442 of another one of the two wave-shaped slots 44, so that the wave crest 441 and the corresponding wave trough 442 can have the minimum width Wmin therebetween, thereby effectively preventing the adhesive layer 4 from having insufficient structural strength of due to the wave-shaped slots 44.

### Fifth Embodiment

As shown in FIG. 9, the adhesive layer 4 has the wave-shaped slots 44 and the buffering cavities 43, and the structures of the wave-shaped slots 44 and the buffering cavities 43 have been described in the above configurations. The following description only describes the arrangement of the wave-shaped slots 44 and the buffering cavities 43 for the sake of brevity. The wave-shaped slots 44 are respectively formed on two of the segments 4a, a part of (e.g., at least one of) the buffering cavities 43 is arranged between the wave-shaped slots 44, and the other buffering cavities 43 are arranged in another two of the segments 4a that are provided without the wave-shaped slots 44.

### Sixth Embodiment

As shown in FIG. 10, the adhesive layer 4 (only) has the rectangular slots 45 respectively formed on the segments 4a. Any two of the rectangular slots 45 located adjacent to each other, formed on a same one of the segments 4a, and respectively arranged on the inner side 41 and the outer side 42 are not overlapped with each other along the width direction W1, W2, but the present disclosure is not limited thereto. For example, in other embodiments of the present disclosure not shown in the drawings, the rectangular slots 45 can be only formed on one of the segments 4a of the adhesive layer 4.

Specifically, any one of the rectangular slots 45 has a slot opening 451 arranged on the inner side 41 or the outer side 42 and a slot bottom 452 that is arranged away from the slot opening 451. Moreover, in any two of the rectangular slots 45 formed on a same one of the segments 4a and respectively arranged on the inner side 41 and the outer side 42, the slot bottoms 452 are preferably coplanar with each other, but the present disclosure is not limited thereto.

In other words, the slot opening 451 has a slot width W451. Any two of the rectangular slots 45 located adjacent to each other, arranged on a same one of the segments 4a, and respectively arranged on the inner side 41 and the outer side 42 have a distance D1 therebetween that is greater than or equal to the slot width W451. Moreover, any two of the rectangular slots 45 located adjacent to each other, arranged on a same one of the segments 4a, and both arranged on the inner side 41 or the outer side 42 have a distance D2 therebetween that is at least three times of the slot width W451, but the present disclosure is not limited thereto.

### Seventh Embodiment

As shown in FIG. 11, the adhesive layer 4 has the rectangular slots 45 and the buffering cavities 43, and the structures of the rectangular slots 45 and the buffering cavities 43 have been described in the above configurations. The following description only describes the arrangement of the rectangular slots 45 and the buffering cavities 43 for the sake of brevity. The rectangular slots 45 are respectively formed on two of the segments 4a, and the buffering cavities 43 are arranged in another two of the segments 4a that are provided without the rectangular slots 45.

### Beneficial Effects of the Embodiment

In conclusion, when the sensor package structure provided by the present disclosure has a high temperature (or is heated), the adhesive layer can be selectively formed with at least one type of the L number of the buffering cavities, the M number of the wave-shaped slots, and the N number of the rectangular slots (e.g., the adhesive layer has the wave-shaped slots or the rectangular slots), thereby effectively reducing a stress strength generated from the adhesive layer. Accordingly, problems relating to delamination of the adhesive layer or damage of the component adhered to the adhesive layer (e.g., the sensor chip or the light-permeable layer) can be improved.

Moreover, in the sensor package structure provided by the present disclosure, the adhesive layer meets a specific structural condition (e.g., the minimum width is greater than or equal to 50% of the predetermined width), so that a quantity and an arrangement of any one type of the buffering cavities, the wave-shaped slots, and the rectangular slots formed on the adhesive layer can be adjusted or changed for meeting different design requirements.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A sensor package structure, comprising:
a substrate;
a sensor chip disposed on the substrate along a predetermined direction and electrically coupled to the substrate, wherein a top surface of the sensor chip has a sensing region and a carrying region that surrounds the sensing region;
an adhesive layer having a ring shape and being disposed on the carrying region of the sensor chip, wherein the adhesive layer has an inner side and an outer side that is opposite to the inner side and that is spaced apart from the inner side by a predetermined width along a width direction perpendicular to the predetermined direction, wherein the adhesive layer has at least one of an L number of buffering cavities, an M number of wave-shaped slots, and an N number of rectangular slots, in which L is a positive integer, and any one of M and N is a positive integer greater than one; wherein, in a cross-sectional view of the adhesive layer perpendicular to the predetermined direction, a minimum width of the adhesive layer in the width direction is greater than or equal to 50% of the predetermined width;
a light-permeable layer having an outer surface and an inner surface that is opposite to the outer surface, wherein the light-permeable layer is disposed on the adhesive layer, and the inner surface of the light-permeable layer, the inner side of the adhesive layer, and the sensor chip jointly define an enclosed space; and
an encapsulant formed on the substrate, wherein the sensor chip, the adhesive layer, and the light-permeable layer are embedded in the encapsulant, and the outer surface of the light-permeable layer is at least partially exposed from the encapsulant;
wherein, when the adhesive layer has the L number of the buffering cavities, each of the L number of the buffering cavities is arranged in the adhesive layer and penetrates through the adhesive layer along the predetermined direction;
wherein, when the adhesive layer has the M number of the wave-shaped slots, the M number of the wave-shaped slots are respectively recessed in the inner side and the outer side of the adhesive layer and penetrate through the adhesive layer along the predetermined direction, and any two of the M number of the wave-shaped slots located adjacent to each other and respectively arranged on the inner side and the outer side are only partially overlapped with each other along the width direction;
wherein, when the adhesive layer has the N number of the rectangular slots, the N number of the rectangular slots are respectively recessed in the inner side and the outer side of the adhesive layer and penetrate through the adhesive layer along the predetermined direction, and any two of the N number of the rectangular slots located adjacent to each other and respectively arranged on the inner side and the outer side are not overlapped with each other along the width direction.

2. The sensor package structure according to claim 1, wherein, when the adhesive layer has the L number of the buffering cavities and L is a positive integer greater than one, any two of the L number of the buffering cavities located adjacent to each other are not overlapped with each other along the width direction.

3. The sensor package structure according to claim 1, wherein, when the adhesive layer has the L number of the buffering cavities and L is a positive integer greater than one, each of the L number of the buffering cavities is overlapped with at least one of the L number of the buffering cavities along the width direction.

4. The sensor package structure according to claim 1, wherein, when the adhesive layer has the L number of the buffering cavities, in the cross-sectional view of the adhesive layer, a total area of the L number of the buffering cavities is less than or equal to 50% of an area jointly surrounded by the inner side and the outer side of the adhesive layer.

5. The sensor package structure according to claim 1, wherein the adhesive layer includes a plurality of segments sequentially connected to form the ring shape, and wherein, when the adhesive layer has the L number of the buffering cavities, the L number of the buffering cavities are arranged in at least one of the segments.

6. The sensor package structure according to claim 1, wherein, when the adhesive layer has the L number of the buffering cavities and L is a positive integer greater than one, any one of the L number of the buffering cavities is symmetrical to another one of the L number of the buffering cavities relative to a center of the sensing region.

7. The sensor package structure according to claim 1, wherein the adhesive layer includes a plurality of segments sequentially connected to form the ring shape, and wherein, when the adhesive layer has the M number of the wave-shaped slots and the N number of the rectangular slots, the M number of the wave-shaped slots are formed on one of the segments, and the N number of the rectangular slots are formed on another one of the segments.

8. The sensor package structure according to claim 1, wherein, when the adhesive layer has the L number of the buffering cavities, the M number of the wave-shaped slots, and the N number of the rectangular slots, the L number of the buffering cavities do not correspond in position to any one of the M number of the wave-shaped slots and any one of the N number of the rectangular slots along the width direction.

9. A sensor package structure, comprising:
a substrate;
a sensor chip disposed on the substrate along a predetermined direction and electrically coupled to the substrate, wherein a top surface of the sensor chip has a sensing region and a carrying region that surrounds the sensing region;
an adhesive layer having a ring shape and being disposed on the carrying region of the sensor chip, wherein the adhesive layer has an inner side and an outer side that is opposite to the inner side and that is spaced apart from the inner side by a predetermined width along a width direction perpendicular to the predetermined direction, wherein the adhesive layer has a plurality of wave-shaped slots respectively recessed in the inner side and the outer side thereof and penetrating therethrough along the predetermined direction, wherein any two of the wave-shaped slots located adjacent to each other and respectively arranged on the inner side and the outer side are only partially overlapped with each other along the width direction, and wherein, in a cross-sectional view of the adhesive layer perpendicular to the predetermined direction, a minimum width of the adhesive layer in the width direction is greater than or equal to 50% of the predetermined width;
a light-permeable layer having an outer surface and an inner surface that is opposite to the outer surface, wherein the light-permeable layer is disposed on the adhesive layer, and the inner surface of the light-permeable layer, the inner side of the adhesive layer, and the sensor chip jointly define an enclosed space; and
an encapsulant formed on the substrate, wherein the sensor chip, the adhesive layer, and the light-permeable layer are embedded in the encapsulant, and the outer surface of the light-permeable layer is at least partially exposed from the encapsulant.

10. The sensor package structure according to claim 9, wherein, in any two of the M number of the wave-shaped slots located adjacent to each other and respectively arranged on the inner side and the outer side, a wave crest of one of the two wave-shaped slots corresponds in position to a wave trough of another one of the two wave-shaped slots along the width direction.

11. The sensor package structure according to claim 9, wherein the adhesive layer includes a plurality of segments sequentially connected to form the ring shape, and wherein the wave-shaped slots are formed on at least one of the segments.

12. The sensor package structure according to claim 9, wherein the adhesive layer has at least one buffering cavity arranged therein and penetrating therethrough along the predetermined direction.

13. The sensor package structure according to claim 12, wherein the at least one buffering cavity is located between the wave-shaped slots.

14. A sensor package structure, comprising:
a substrate;
a sensor chip disposed on the substrate along a predetermined direction and electrically coupled to the substrate, wherein a top surface of the sensor chip has a sensing region and a carrying region that surrounds the sensing region;
an adhesive layer having a ring shape and being disposed on the carrying region of the sensor chip, wherein the adhesive layer has an inner side and an outer side that is opposite to the inner side and that is spaced apart from the inner side by a predetermined width along a width direction perpendicular to the predetermined direction, wherein the adhesive layer has a plurality of rectangular slots respectively recessed in the inner side and the outer side thereof and penetrating therethrough along the predetermined direction, wherein any two of the rectangular slots located adjacent to each other and respectively arranged on the inner side and the outer side are not overlapped with each other along the width direction, and wherein, in a cross-sectional view of the adhesive layer perpendicular to the predetermined direction, a minimum width of the adhesive layer in the width direction is greater than or equal to 50% of the predetermined width;
a light-permeable layer having an outer surface and an inner surface that is opposite to the outer surface, wherein the light-permeable layer is disposed on the adhesive layer, and the inner surface of the light-permeable layer, the inner side of the adhesive layer, and the sensor chip jointly define an enclosed space; and
an encapsulant formed on the substrate, wherein the sensor chip, the adhesive layer, and the light-permeable layer are embedded in the encapsulant, and the outer surface of the light-permeable layer is at least partially exposed from the encapsulant.

15. The sensor package structure according to claim 14, wherein any one of the rectangular slots has a slot opening arranged on the inner side or the outer side of the adhesive layer and having a slot width, and wherein any two of the rectangular slots located adjacent to each other and respectively arranged on the inner side and the outer side of the adhesive layer have a distance therebetween that is greater than or equal to the slot width.

16. The sensor package structure according to claim 14, wherein any one of the rectangular slots has a slot opening arranged on the inner side or the outer side of the adhesive layer and having a slot width, and wherein any two of the rectangular slots located adjacent to each other and both arranged on the inner side or the outer side have a distance therebetween that is at least three times of the slot width.

17. The sensor package structure according to claim 14, wherein the adhesive layer includes a plurality of segments sequentially connected to form the ring shape, and wherein the rectangular slots are formed on at least one of the segments.

18. The sensor package structure according to claim 17, wherein any one of the rectangular slots has a slot opening arranged on the inner side or the outer side of the adhesive layer and a slot bottom that is arranged away from the slot opening, and wherein, in any two of the rectangular slots formed on a same one of the segments and respectively arranged on the inner side and the outer side, the slot bottoms are coplanar with each other.

19. The sensor package structure according to claim 14, wherein the adhesive layer has at least one buffering cavity arranged therein and penetrating therethrough along the predetermined direction.
